(19) United States
(12) Patent Application Publication
(10) Pub. No.: US 2017/0171971 A1
(43) Pub. Date: Jun. 15, 2017

(54) POLYIMIDE, POLYIMIDE FILM, AND FLEXIBLE COPPER-COATED LAMINATE

(71) Applicant: TAIFLEX Scientific Co., Ltd., KAOHSIUNG (TW)

(72) Inventors: Shih-Chang Lin, KAOHSIUNG (TW); Chiu-Feng Chen, KAOHSIUNG (TW); Sheng-Chin Lin, KAOHSIUNG (TW); Ching-Hung Huang, KAOHSIUNG (TW); Kuang-Ting Hsueh, KAOHSIUNG (TW)

(21) Appl. No.: 15/057,127

(22) Filed: Mar. 1, 2016

(30) Foreign Application Priority Data
Dec. 9, 2015 (TW) 104141277

(51) Int. Cl. H05K 1/05; C09D 179/08

(52) U.S. Cl. CPC H05K 1/056; C09D 179/08

(57) ABSTRACT

A polyimide is provided. The polyimide includes a repeating unit represented by formula 1:

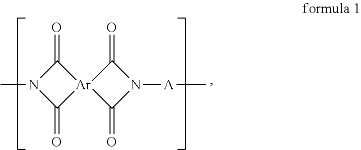

wherein
Ar is a tetravalent residue obtainable from an aromatic tetracarboxylic dianhydride; and

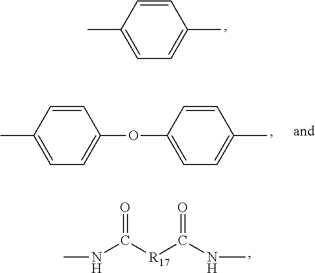

A includes
   wherein R₁₇ is a single bond or a C1-C18 divalent linking group.

### CROSS-REFERENCE TO RELATED APPLICATION

This application claims the priority benefit of Taiwan application serial no. 104141277, filed on Dec. 9, 2015. The entirety of the above-mentioned patent application is hereby incorporated by reference herein and made a part of this specification.

### BACKGROUND OF THE INVENTION

Field of the Invention

The invention relates to a polyimide, a polyimide film, and a flexible copper-coated laminate, and more particularly, to a polyimide having good adhesive force with copper foil, a polyimide film having the polyimide, and a flexible copper-coated laminate including the polyimide film.

Description of Related Art

As electronic products are gradually developed to be lighter and thinner, the usage demand for flexible circuit boards has also significantly increased. The main upstream material of the flexible circuit board is a flexible copper-coated laminate. Currently, since the adhesive force between a polyimide film and copper foil (in particular rolled copper foil having low surface roughness and smaller thickness) is small, an adhesive layer generally needs to be disposed between the two for bonding. However, as a result, not only is the flexible copper-coated laminate limited in the thinning aspect, but the issue of significant curling also readily occurs. Therefore, the development of a flexible copper-coated laminate having good flatness and for which an adhesive layer is not needed is a very important object of development in the art.

### SUMMARY OF THE INVENTION

The invention provides a polyimide having a novel structure, and a polyimide film including the polyimide. And, the polyimide film has good adhesive force with copper foil, and the bonded structure of the two has good flatness. Moreover, the polyimide film is suitable for application in a flexible copper-coated laminate.

A polyimide of the invention includes a repeating unit represented by formula 1:

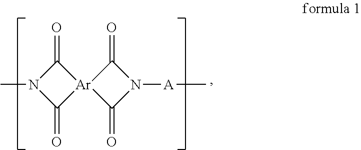

wherein
Ar is a tetravalent residue obtainable from an aromatic tetracarboxylic dianhydride; and

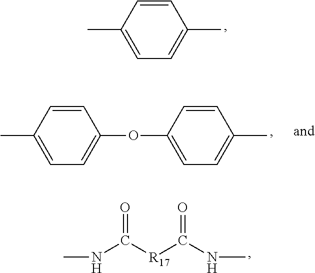

A includes
   wherein R₁₇ is a single bond or a C1-C18 divalent linking group.

In an embodiment of the invention,

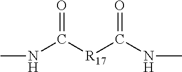

is a divalent group derived from a dihydrazide compound, wherein the dihydrazide compound is adipic dihydrazide, 4-isopropyl-2,5-dioxoimidazolidine-1,3-di(propionohydrazide), or 1,18-(hydrazinocarbonyl)-7,11-octadecadiene.

In an embodiment of the invention, R₁₇ is a C4-C18 divalent linking group.

In an embodiment of the invention, the aromatic tetracarboxylic dianhydride comprises a tetracarboxylic dianhydride containing a single aromatic group and a tetracarboxylic dianhydride containing two aromatic groups.

In an embodiment of the invention, Ar includes

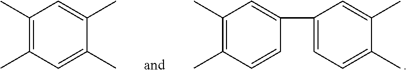

In an embodiment of the invention, the polyimide contains greater than 0 and less than 0.2 mole percent of the repeating unit represented by formula 1 in the form of Ar is

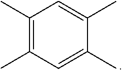

In an embodiment of the invention,

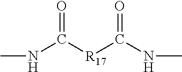

is present in amounts from 3 to 15 mole percent of combined moles of

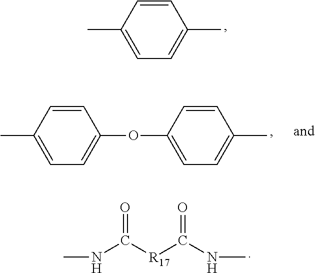

In an embodiment of the invention,

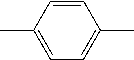

is present in amounts from 75 to 92 mole percent of combined moles of

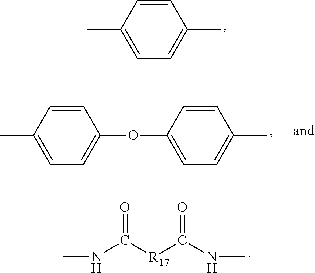

In an embodiment of the invention,

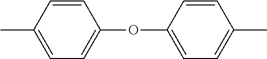

is present in amounts from 5 to 10 mole percent of combined moles of

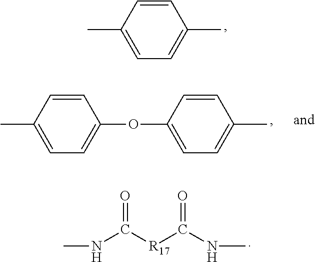

A polyimide film of the invention is obtained from the above polyimide.

In an embodiment of the invention, the peel strength of the polyimide film is 0.4 kgf/cm to 0.7 kgf/cm.

A flexible copper-coated laminate of the invention includes a copper foil and the above polyimide film. The polyimide film is directly disposed on the copper foil.

In an embodiment of the invention, the peel strength of the polyimide film is 0.4 kgf/cm to 0.7 kgf/cm.

Based on the above, the polyimide provided in the invention is manufactured by using three specific diamine monomers and a aromatic tetracarboxylic dianhydride. As a result, the polyimide and the polyimide film including the same can have good adhesive force with copper foil, and the bonded structure can have good flatness.

To make the above features and advantages of the invention more comprehensible, several embodiments are described in detail as follows.

### DESCRIPTION OF THE EMBODIMENTS

In the present specification, a range represented by “a numerical value to another numerical value” is a schematic representation for avoiding listing all of the numerical values in the range in the specification. Therefore, the recitation of a specific numerical range covers any numerical value in the numerical range and a smaller numerical range defined by any numerical value in the numerical range, as is the case with any numerical value and a smaller numerical range thereof in the specification.

In the present specification, skeleton formulas are sometimes used to represent the structures of polymers or groups. Such representation can omit carbon atoms, hydrogen atoms, and carbon-hydrogen bonds. Of course, structural formulas with clear illustrations of atoms or atomic groups are definitive.

To prepare a polyimide having good adhesive force with copper foil, the invention provides a polyimide capable of achieving the above advantages. In the following, embodiments are listed as examples of actual implementation of the invention.

An embodiment of the invention provides a polyimide including the repeating unit represented by formula 1:

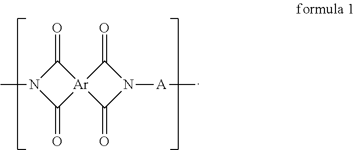

In formula 1, Ar is a tetravalent residue obtainable from an aromatic tetracarboxylic dianhydride. In other words, Ar is a residual group of the aromatic tetracarboxylic dianhydride other than 2 carboxylic acid anhydride groups (—(CO)₂O). In the present specification, the aromatic tetracarboxylic dianhydride is also referred to as a dianhydride monomer.

Specifically, in the present embodiment, the aromatic tetracarboxylic dianhydride includes a tetracarboxylic dianhydride containing a single aromatic group and a tetracarboxylic dianhydride containing two aromatic groups. In other words, in the present embodiment, when the repeating unit represented by formula 1 is prepared, a plurality of dianhydride monomers can be adopted.

Specifically, Ar includes

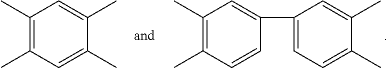

In other words, the repeating unit represented by formula 1 is prepared using two dianhydride monomers, and the two dianhydride monomers are respectively pyromellitic dianhydride (PMDA), and 3,3′,4,4′-biphenyltetracarboxylic dianhydride (BPDA). Moreover, in the present embodiment, the polyimide contains greater than 0 and less than 0.2 mole percent of the repeating unit represented by formula 1 in the form of Ar is

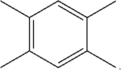

Specifically, when the polyimide contains greater than 0 and less than 0.2 mole percent of the repeating unit represented by formula 1 in the form of Ar is

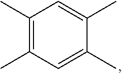

the texture of the polyimide film prepared by the polyimide is more brittle, and therefore the polyimide film has poor applicability.

In formula 1, A includes

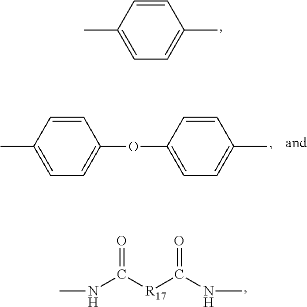

wherein R₁₇ is a single bond or a C1-C18 divalent linking group.

Specifically, A is a residual group of the diamine compound other than 2 amino groups (—NH₂). In other words, in the present embodiment, the repeating unit represented by formula 1 is obtained by reacting three diamine compounds and a aromatic tetracarboxylic dianhydride. In the present specification, the diamine compound used in the preparation of the repeating unit represented by formula 1 is also referred to as a diamine monomer.

Specifically, in the present embodiment, the diamine monomers used in the preparation of the repeating unit represented by formula 1 are p-phenylenediamine (PDA), 4,4′-oxydianiline (ODA), and a dihydrazide compound. In other words,

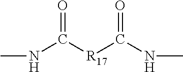

is a divalent group derived from the dihydrazide compound.

In the present embodiment, the dihydrazide compound can be adipic dihydrazide, 4-isopropyl-2,5-dioxoimidazolidine-1,3-di(propionohydrazide), or 1,18-(hydrazinocarbonyl)-7,11-octadecadiene. From another perspective, in the present embodiment, R₁₇ is preferably a C4-C18 divalent linking group.

Moreover, as described above, the polyimide including the repeating unit represented by formula 1 can be prepared by reacting two dianhydride monomers and three diamine monomers, and the method thereof can include the following steps. First, in a water bath (room temperature), PDA, ODA, and a dihydrazide compound are added in a solvent to perform mixing, and after the components are completely dissolved, a diamine monomer mixture is formed. In this step, PDA is, for instance, present in amounts from 75 to 92 mole percent of combined moles of PDA, ODA, and the dihydrazide compound, ODA is, for instance, present in amounts from 5 to 10 mole percent of combined moles of PDA, ODA, and the dihydrazide compound, and the dihydrazide compound is, for instance, present in amounts from 3 to 15 mole percent of combined moles of PDA, ODA, and the dihydrazide compound; and the solvent is, for instance, a high-polarity solvent such as hexamethylphosphoramide (HMPA), N,N-dimethylacetamide (DMAc), N-methyl-2-pyrrolidone (NMP), 1,3-dimethyl imidazolinone (DMI), or m-cresol.

Then, in a water bath (room temperature), pyromellitic dianhydride (PMDA) and 3,3′,4,4′-biphenyl tetracarboxylic dianhydride (BPDA) mixed beforehand are added in the diamine monomer mixture to react, so as to form a polyamide acid solution. In this step, based on the total moles of PMDA and BPDA, the mole percentage of PMDA is, for instance, greater than 0% and less than 20%, preferably 5% to 15%, and the mole percentage of BPDA is, for instance, greater than 80% and less than 100%, preferably 85% to 95%; the reaction time is, for instance, 12 hours to 24 hours; and the solid content of the polyamide acid solution is, for instance, 14% to 16%.

Then, in a nitrogen gas atmosphere, an imidization reaction (dehydration-cyclization) is performed on the polyamide acid solution to form the polyimide represented by formula 1. Specifically, the dehydration-cyclization can be performed by, for instance, first performing baking on the polyamide acid solution at 120° C. to 140° C. for 10 minutes to 30 minutes without using a catalyst to remove the solvent, and then increasing the temperature to 300° C. to 350° C. to react for 30 minutes to 60 minutes. However, the invention is not limited thereto. In other embodiments, the dehydration-cyclization can also be performed in the presence of a catalyst.

It should be mentioned that, in the present embodiment, the polyimide is prepared by using the aromatic tetracarboxylic dianhydride (i.e., pyromellitic dianhydride and 3,3′,4,4′-biphenyl tetracarboxylic dianhydride) as the dianhydride monomer, and by using PDA, ODA, and the dihydrazide compound as the diamine monomers, and therefore the polyimide can have good adhesive force with copper foil. As a result, the polyimide can be suitable for the manufacture of a flexible copper-coated laminate.

Moreover, the polyimide of the invention can exist in the form of, for instance, a thin film, powder, or a solution. In the following, the polyimide is exemplified by a thin film.

Another embodiment of the invention provides a polyimide film obtained from the polyimide in any one of the above embodiments. In the present embodiment, the thickness of the polyimide film is between about 15 μm and about 25 μm. In the present embodiment, the peel strength of the polyimide film is 0.4 kgf/cm to 0.7 kgf/cm.

Referring to the preparation method of the polyimide above, the manufacturing method of a polyimide film includes forming a polyamide acid solution, then coating the polyamide acid solution on a substrate via a coating process, and then performing an imidization reaction (dehydration-cyclization) on the polyamide acid solution. Specifically, the coating process is, for instance, a blade coating method or a spin coating method; the substrate is, for instance, copper foil; the dehydration-cyclization can be performed by, for instance, first performing baking on the polyamide acid solution at 120° C. to 140° C. for 10 minutes to 30 minutes to remove the solvent, and then increasing the temperature to 300° C. to 350° C. to react for 30 minutes to 60 minutes.

It should be mentioned that, as described above, since the polyimide has good adhesive force with copper foil, the polyimide film similarly has good adhesive force with copper foil, and is suitable for the manufacture of a flexible copper-coated laminate.

Another embodiment of the invention further provides a flexible copper-coated laminate including a copper foil and the polyimide film in any one of the above embodiments, wherein the polyimide film is directly disposed on the copper foil. In other words, in the present embodiment, the polyimide film can be directly bonded with copper foil such that an adhesive layer does not need to be disposed between the two. The copper foil can adopt any copper foil used for a flexible copper-coated laminate known to those skilled in the art, such as rolled copper foil or electrolytic copper foil, and the thickness of the copper foil is also not particularly limited.

Referring to the manufacturing method of a polyimide film above, the manufacturing method of a flexible copper-coated laminate includes: coating a polyamide acid solution on a copper foil via a coating process, and then performing an imidization reaction (dehydration-cyclization) on the polyamide acid solution to form a polyimide film on the copper foil.

It should be mentioned that, as described above, since the polyimide film has good adhesive force with copper foil, the polyimide film in the flexible copper-coated laminate can be directly disposed on the copper foil without the use of an adhesive layer, and the flexible copper-coated laminate can have good flatness. As a result, in comparison to a known flexible copper-coated laminate, the thickness of the flexible copper-coated laminate of the invention is smaller and the flexible copper-coated laminate has good manufacture yield and reliability. Specifically, in the present embodiment, the peel strength of the polyimide film is 0.4 kgf/cm to 0.7 kgf/cm.

The features of the invention are more specifically described in the following with reference to Examples 1 to 4. Although the following Examples 1 to 4 are described, the materials used and the amount and ratio thereof, as well as handling details and handling process . . . etc., can be suitably modified without exceeding the scope of the invention. Accordingly, restrictive interpretation should not be made to the invention based on the examples described below.

Information of the main materials used in the preparation of the polyimide films and the flexible copper-coated laminates of Examples 1 to 4 are as shown below.

Diamine monomer:
p-phenylenediamine (PDA): purchased from Dongxin Chemical Corporation;

4,4′-oxydianiline (ODA): purchased from JFE Chemical Co., Ltd.;

Adipic dihydrazide (ADH): purchased from AJINOMOTO Corporation;

1,18-(hydrazinocarbonyl)-7,11-octadecadiene (UDH): purchased from AJINOMOTO Corporation.

Dianhydride monomer:

3,3′,4,4′-biphenyltetracarboxylic dianhydride (BPDA): purchased from JFE Chemical Co., Ltd.;

pyromellitic dianhydride (PMDA): purchased from JFE Chemical Co., Ltd.

Rolled copper foil: purchased from Nikko Metals Corporation.

### EXAMPLE 1

In a water bath (room temperature), 0.4 g (0.002 mol, 5 mol %) of ODA, 3.98 g (0.037 mol, 92 mol %) of PDA, and 0.21 g (0.001 mol, 3 mol %) of ADH were dissolved in 85 g of NMP used as the solvent to form a diamine monomer mixture. In a water bath (room temperature), 1.57 g (0.007 mol, 18 mol %) of PMDA and 9.42 g (0.032 mol, 80 mol %) of BPDA uniformly mixed beforehand were added in the above diamine monomer mixture. Then, in a water bath (room temperature), reaction was performed for 24 hours to obtain a polyamide acid solution having a solid content of 15%.

Then, 100 ml of the polyamide acid solution was coated on a rolled copper foil (thickness: 12 μm) using a blade coating method, and then baking was performed at 130° C. for 10 minutes to remove the NMP. Then, the rolled copper foil on which the polyamide acid solution was coated was placed in a nitrogen gas atmosphere at 350° C. to perform an imidization reaction for 30 minutes to obtain the flexible copper-coated laminate of Example 1, wherein the imidization ratio is 100%. Lastly, the rolled copper foil was removed via an etching process to obtain the polyimide film of Example 1, wherein the thickness was measured via a Litematic device (Litematic VL-50A made by Mitutoyo America Corporation) to obtain a thickness of about 18 μm.

### EXAMPLE 2 to EXAMPLE 3

The flexible copper-coated laminates and the polyimide films of Example 2 to Example 3 were manufactured according to a similar manufacturing process of Example 1, and the difference was only in: the mole percentage of each of the monomers, as shown in Table 1. Moreover, in Example 2 to Example 3, the solid content of the polyamide acid solution and the thickness of the polyimide film are respectively shown in Table 1.

### EXAMPLE 4

The flexible copper-coated laminate and the polyimide film of Example 4 were manufactured according to a similar manufacturing process of Example 1, and the difference was only in: ADH was replaced by UDH, and the mole percentage of each of the monomers is as shown in Table 1. Moreover, in Example 4, the solid content of the polyamide acid solution and the thickness of the polyimide film are respectively shown in Table 1.

Then, measurements of coefficient of thermal expansion (CTE), thermal decomposition temperature, tensile strength, elongation, tensile elastic modulus, and warpage were performed on the polyimide film of each of Examples 1 to 4, and measurement of peel strength and a solder resistance test were performed on the flexible copper-coated laminates of each of Examples 1 to 4. The above tests are as described below, and the test results are shown in Table 1.

### <Measurement of Coefficient of Thermal Expansion>

First, the polyimide film of each of Examples 1 to 4 was manufactured into a film material having length and width dimensions of 2 mm×30 mm. Then, in a thermo-mechanical analyzer (EXSTAR 6000 made by Seiko Instrument Inc.), each of the film materials was heated from 30° C. to 450° C. under the conditions of a nitrogen gas atmosphere and a heating rate set to 10° C./min, and the average value of dimension variation between 50° C. and 200° C. was calculated to obtain the coefficient of thermal expansion (ppm/° C.). In general, in industries, in terms of the application of the flexible copper-coated laminate, a coefficient of thermal expansion of 30 ppm/° C. or less can be regarded as close to the coefficient of thermal expansion (17 ppm/° C.) of copper foil.

### <Measurement of Thermal Decomposition Temperature>

First, the polyimide film of each of Examples 1 to 4 was used in amount of 0.5 g to 0.8 g as a testing film material. Then, in a thermal-gravimetric analyzer (EXSTAR 6000 made by Seiko Instrument Inc.), each of the film materials was heated from 30° C. to 600° C. under the conditions of a nitrogen gas atmosphere and a heating rate set to 10° C./min, and the temperature measured at a film material weight loss of 5% was used as the thermal decomposition temperature (° C.). In industrial standards, the thermal decomposition temperature of the polyimide film needs to reach at least 400° C., and a greater value means a better thermal stability.

### <Measurements of Tensile Strength, Elongation, and Tensile Modulus of Elasticity>

First, the polyimide film of each of Examples 1 to 4 was manufactured into a film material having length (spacing of marks) and width dimensions of 25.4 mm×3.2 mm and having a dumbbell shape or a dog bone shape. Then, the tensile strength (MPa), the elongation (%), and the tensile elastic modulus (GPa) of each of the film materials were measured using a universal testing machine (AG-1S made by Shimadzu Scientific Instruments Co., Ltd.).

Tensile strength represents the maximum intensity which the film material can withstand during the stretching process. Specifically, tensile strength is the maximum engineering stress at which the film material is stretched to a stretch length before breaking under the condition of an initial tensile strength setting of zero, wherein a greater value means a better mechanical property.

Elongation represents the degree of deformation when the film material is broken. Specifically, elongation is the degree of deformation obtained when the film material is stretched to the point of breaking under the condition of an initial tensile strength setting of zero, wherein a greater value means a better mechanical property.

Tensile elastic modulus (or Young's Modulus) represents the indication of the degree of difficulty which the film material is elastically deformed. A greater value means a greater stress needed for elastic deformation, i.e., the stiffness of the material is greater; a smaller value means a better flexibility or softness.

### <Measurement of Warpage>

First, the polyimide film of each of Examples 1 to 4 obtained after the rolled copper foil was etched and removed was placed on a flat surface. Then, the tilt heights of the four corners of each of the polyimide films were measured using a ruler, and an average value was obtained. A height average value less than 1 mm is considered good, i.e., the polyimide film has good flatness; a height average value greater than or equal to 1 mm is considered poor.

### <Measurement of Peel Strength>

First, the flexible copper-coated laminate of each of Examples 1 to 4 was cut into a test sample having a width of 0.3175 mm. Then, each of the test samples was stretched to a stretch length of 30 mm using a universal testing machine (AG-1S made by Shimadzu Scientific Instruments Co., Ltd.) under the condition of a tensile speed set to 50.8 mm/min, and the peel strength (kgf/cm) at this point was obtained. It should be mentioned that, a greater adhesive force between the polyimide film and the rolled copper foil means that the interface between the two is less readily damaged by external force. In other words, in Table 1, a higher value of the peel strength means a better peel strength and a better adhesive force between the polyimide film and the rolled copper foil.

### <Solder Resistance Test>

A solder resistance test was performed on the flexible copper-coated laminate of each of Examples 1 to 4 according to the specifications of IPC-TM-650 No. 2.4.13. In the test, if the flexible copper-coated laminate did not explode under a temperature of 300° C. over a period of 30 seconds, then “◯” is indicated in Table 1, and if the flexible copper-coated laminate exploded under a temperature of 300° C. over a period of 30 seconds, then “x” is indicated in Table 1.

TABLE 1

| | Example 1 | Example 2 | Example 3 | Example 4 |
|---|---|---|---|---|
| ODA (mol %) | 5 | 5 | 5 | 5 |
| PDA (mol %) | 92 | 95 | 85 | 95 |
| ADH (mol %) | 3 | 5 | 10 | — |
| UDH (mol %) | — | — | — | 5 |
| PMDA (mol %) | 18 | 18 | 18 | 18 |
| BPDA (mol %) | 82 | 82 | 82 | 82 |
| Solid content of | 15 | 15 | 15 | 15 |
| polyamide acid | | | | |
| solution (%) | | | | |
| Thickness of polyimide | 18 | 18 | 18 | 18 |
| film (μm) | | | | |
| Coefficient of thermal | 10.78 | 11.05 | 12.36 | 16.65 |
| expansion (ppm/° C.) | | | | |
| Thermal decomposition | 599 | 593 | 558 | 554 |
| temperature (° C.) | | | | |
| Tensile strength (MPa) | 350.5 | 317.1 | 235.52 | 248.1 |
| Elongation (%) | 23.40 | 18.27 | 9.55 | 15.08 |
| Tensile elastic modulus | 6.20 | 6.03 | 5.34 | 5.01 |
| (GPa) | | | | |
| Warpage measurement | Good | Good | Good | Good |
| Peel strength (kgf/cm) | 0.605 | 0.617 | 0.602 | 0.606 |
| Solder resistance test | ◯ | ◯ | ◯ | ◯ |

Unit mol % represents: based on the total moles of ODA, PDA, and ADH or based on the total moles of ODA, PDA, and UDH

It can be known from Table 1 that, the polyimide films of Examples 1 to 4 all had good performance in thermal decomposition temperature, tensile strength, elongation, and elastic modulus. In other words, the polyimide films of Examples 1 to 4 had good thermal properties and mechanical properties.

Moreover, it can be known from Table 1 that, the coefficients of thermal expansion of the polyimide films of Examples 1 to 4 were between 10.78 ppm/° C. and 16.65 ppm/° C., i.e., the coefficients of thermal expansion of the polyimide films of Examples 1 to 4 were close to the coefficient of thermal expansion of copper foil, such that dimension variation of the polyimide film caused by the high-temperature process in the manufacture of the flexible copper-coated laminate can be effectively inhibited. As a result, the occurrence of alignment offset can be prevented, such that dimensional stability of the flexible copper-coated laminate is increased.

Moreover, it can be known from Table 1 that, the polyimide films of Examples 1 to 4 all had good warpage performance, i.e., the polyimide films of Examples 1 to 4 had good flatness. Moreover, it can be known from Table 1 that, the peel strengths of the polyimide films of Examples 1 to 4 were all greater than 0.6 kgf/cm, i.e., the polyimide films of Examples 1 to 4 had good adhesive force with copper foil.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A polyimide, comprising a repeating unit represented by formula 1: 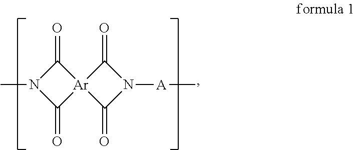
wherein
Ar is a tetravalent residue obtainable from an aromatic tetracarboxylic dianhydride; and
A comprises 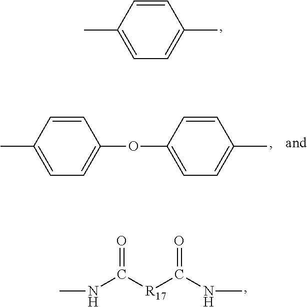
wherein R₁₇ is a single bond or a C1-C18 divalent linking group.

2. The polyimide of claim 1, wherein 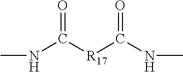
is a divalent group derived from a dihydrazide compound, wherein the dihydrazide compound is adipic dihydrazide, 4-isopropyl-2,5-dioxoimidazolidine-1,3-di(propionohydrazide), or 1,18-(hydrazinocarbonyl)-7,11-octadecadiene.

3. The polyimide of claim 1, wherein R₁₇ is a C4-C18 divalent linking group.

4. The polyimide of claim 1, wherein the aromatic tetracarboxylic dianhydride comprises a tetracarboxylic dianhydride containing a single aromatic group and a tetracarboxylic dianhydride containing two aromatic groups.

5. The polyimide of claim 4, wherein Ar comprises

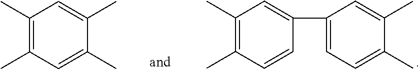

6. The polyimide of claim 5, wherein the polyimide contains greater than 0 and less than 0.2 mole percent of the repeating unit represented by formula 1 in the form of Ar is

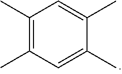

7. The polyimide of claim 1, wherein 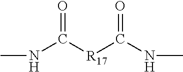
is present in amounts from 3 to 15 mole percent of combined moles of

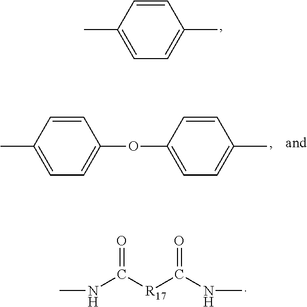

8. The polyimide of claim 1, wherein 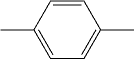
is present in amounts from 75 to 92 mole percent of combined moles of

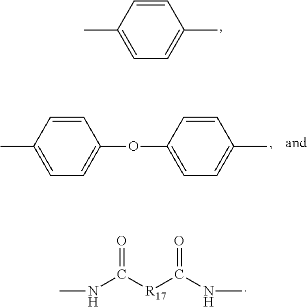

9. The polyimide of claim 1, wherein 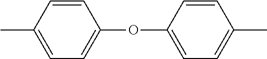
is present in amounts from 5 to 10 mole percent of combined moles of

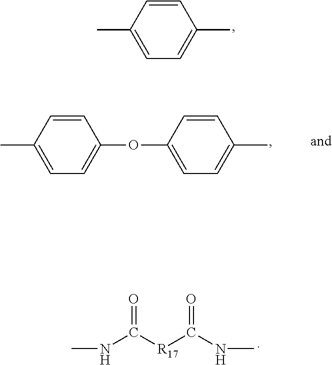

10. A polyimide film, obtained from the polyimide of claim 1.

11. The polyimide film of claim 10, wherein a peel strength of the polyimide film is 0.4 kgf/cm to 0.7 kgf/cm.

12. A flexible copper-coated laminate, comprising:
a copper foil; and
a polyimide film directly disposed on the copper foil, wherein the polyimide film is the polyimide film of claim 10.

13. The flexible copper-coated laminate of claim 12, wherein a peel strength of the polyimide film is 0.4 kgf/cm to 0.7 kgf/cm.
